(19) United States
(12) Patent Application Publication
(10) Pub. No.: US 2023/0200085 A1
(43) Pub. Date: Jun. 22, 2023

(54) ELECTRONIC COMPONENT WITH AT LEAST ONE LAYER OF A FERROELECTRIC OR ANTIFERROELECTRIC MATERIAL

(71) Applicant: Fraunhofer-Gesellschaft zur Förderung der Angewandten Forschung E.V., München (DE)

(72) Inventors: Maximilian LEDERER, Dresden (DE); Konrad SEIDEL, Dresden (DE)

(21) Appl. No.: 18/069,411

(22) Filed: Dec. 21, 2022

(30) Foreign Application Priority Data
Dec. 22, 2021 (DE) 10 2021 214 885.9

(51) Int. Cl. H10B 53/30; G11C 11/22; H01L 21/28

(52) U.S. Cl. CPC H10B 53/30; G11C 11/221; H01L 29/40111

(57) ABSTRACT

An electronic component with at least one layer of a ferroelectric or antiferroelectric material. The layer may be provided for setting an imprint with a chemical element as a dopant which has a different number of free outer electrons than a non-oxide element of the ferroelectric or antiferroelectric material, and is introduced into the layer in a locally inhomogeneous distribution.

### FIELD

The present invention relates to a component having at least one layer of a ferroelectric or antiferroelectric material and to a method of manufacturing said component.

### BACKGROUND

Ferroelectric materials, i.e. materials whose unit cell has a permanent electric dipole moment that can be switched by an application of an external electric field, are increasingly used in various electronic applications due to their properties. However, a so-called imprint often occurs in ferroelectric devices, i.e. devices containing a ferroelectric material. An imprint is a shift of the polarization curve across the stress axis. This imprint is partially unintentional, but is also needed in certain applications, for example, for non-volatile application on antiferroelectric layers. For example, a method for minimizing the Imprint is known from patent U.S. Pat. No. 9,240,440 B1.

So far, such imprints have been realized via various electrode materials. However, these are usually not compatible with CMOS (complementary metal-oxide-semiconductor) processes and therefore cannot be applied in industrial cleanrooms.

The present invention is therefore based on the object of proposing a component or part as well as a method for its manufacture, with which an imprint can be selectively set for ferroelectric or antiferroelectric layers.

### SUMMARY

This object is solved according to the invention by an electronic component and a method according to the independent claims. Advantageous embodiments and further developments are contained in the dependent claims.

In an electronic component having at least one layer of a ferroelectric or antiferroelectric material, this layer is provided with a chemical element as a dopant (also referred to as a dopant) for setting an imprint, which has a different number of free outer electrons compared with a non-oxide element of the ferroelectric or antiferroelectric material. The dopant is introduced into or contained in the layer in a locally inhomogeneous distribution.

By locally inhomogeneously introducing a dopant with the described properties, i.e. the proportions of the chemical element used for doping in the volume of the layer, vacancies are selectively introduced into the layer, creating an internal electric field and thus a defined imprint. These vacancies also form interference points for domain wall motion, which can induce steeper (and thus generally faster) switching and directionality of switching behavior. The doping is also fully compatible with CMOS processes and can therefore be used in industrial cleanroom production without any problems. The non-oxide element shall be understood to mean, in particular, a chemical element that is not oxygen and typically forms the ferroelectric material in combination with oxygen.

It may be provided that the chemical element forming the dopant is contained or introduced in a proportion relative to the material with which the layer is formed of between 1 percent and 10 percent, i.e. preferably in the single-digit range, the percentages being able to refer both to mass percent and to volume percent, i.e. a dopant concentration lies in the said range. This efficiently produces the described effect without excessive modification of the ferroelectric or antiferroelectric layer. The dopant concentration depends on the desired properties: If antiferroelectric behavior is desired, higher concentrations should be used, for ferroelectric behavior rather lower dopant concentrations. In addition, each layer can also have a different dopant concentration from adjacent layers to adjust the properties as desired.

Preferably, the ferroelectric layer is formed of a ferroelectric material having a fluorite structure, and in a particularly preferred manner, the ferroelectric material is hafnium oxide or zirconium oxide, i.e., the non-oxide element is hafnium or zirconium. This allows the use of common materials for ferroelectric applications, which are also easy to dope. An antiferroelectric layer can be achieved by adjusting the dopant concentration, as explained earlier.

The chemical element or dopant or dopant may be introduced into or contained within the layer in an asymmetric distribution. This allows a more targeted setting of the imprint.

In this context, an asymmetric distribution should be understood to mean, in particular, that the distribution in the layer has no axes of symmetry. This means that parallel to the current flow direction symmetry axes cannot be defined. Also all other axes which can be defined between the axis parallel to the current direction and the axis perpendicular to the current direction do not represent symmetry axes. Thus, an asymmetric distribution means a completely asymmetric distribution of the chemical element or dopant.

Typically, the chemical element as a dopant is selected from aluminum, lanthanum, and, respectively, or yttrium to be able to set the desired properties. Silicon and zirconium are preferably used to stabilize the ferroelectric phase, i.e. incorporated into the material. If hafnium oxide is used, this can also be doped with zirconium oxide, and if zirconium oxide is used, this can also be doped with hafnium.

It can also be provided that the layer is formed with an antiferroelectric material in which the chemical element used for the doping is contained in the layer material or is introduced into it in such a way that when the external electrical potential is neutral, the polarization of this layer does not switch back. Thus, non-volatile memory devices with fast switching behavior and adjustable low switching voltages can be manufactured. In addition, the electronic component based on the doped antiferroelectric material can be designed as a buffer capacitor whose antiferroelectric switching voltage the antiferroelectric energy absorption or energy dissipation can thus be adjusted by the doping.

In a method of producing an electronic component having at least one layer of a ferroelectric or antiferroelectric material, the layer for setting an imprint is provided with a chemical element as a dopant, which has a different number of free outer electrons compared with a non-oxide main element of the ferroelectric or antiferroelectric material and is introduced into the layer in a locally inhomogeneous distribution, i.e. is contained in the layer in this distribution. The inhomogeneous distribution is usually adjusted during deposition, for example by using atomic layer deposition to deposit the layers one after the other, for example with different cycle ratios of monolayers of dopant and hafnium or zirconium. Alternatively, this can also be done by means of physical vapor deposition.

The electronic component produced by this method may have the properties described above, i.e. the method is suitable for producing such a component.

### DESCRIPTION OF THE FIGURES

Examples of the invention are shown in the drawings and are explained below with reference to FIGS. 1-4.

Shown are:

FIG. 1 a schematic sectional view of an electronic component with a ferroelectric layer;

FIG. 2 a diagram of the polarization-voltage curve for the component shown in FIG. 1;

FIG. 3 a view corresponding to FIG. 1 of a further component with ferroelectric layer, and

FIG. 4 a view corresponding to FIG. 2 of the polarization-voltage curve for the electronic component shown in FIG. 3.

### DETAILED DESCRIPTION

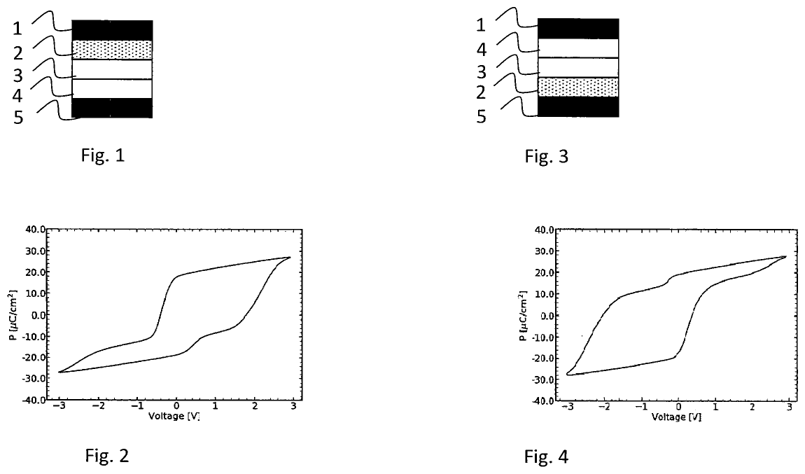

FIG. 1 shows a schematic sectional view of an electronic component in which a multilayer system is arranged between an upper electrode 1 and a lower electrode 5. One of the layers, the top layer in the embodiment example shown in FIG. 1, is made of a ferroelectric material, thus forming ferroelectric layers 2, 3, and 4. The two further layers 3 and 4 are only shown as several layers by way of example. Typically, titanium nitride, TiN, or tantalum nitride, TaN, are used as electrode materials for electrodes 1 and 5. Alternatively, semiconductor materials such as silicon, silicon germanium, SiGe, indium gallium zinc oxide, IGZO, or two-dimensional materials such as graphene can be used.

In the embodiment shown in FIG. 1, the ferroelectric layer is made of hafnium oxide, but in further embodiments it can also be formed of zirconium oxide or generally have a ferroelectric material with a fluoride structure. Alternatively, the ferroelectric layers 2, 3 and 4 may be replaced by an antiferroelectric or antiferroelectric-like layer.

In the embodiment shown, the ferroelectric layer 2 has a dopant added to it, for example the chemical element aluminum, to thus selectively create oxygen vacancies that generate an internal field and thus an imprint. This is achieved by using dopants whose electric charge differs from that of hafnium or zirconium (both 4+). The dopant is introduced into the ferroelectric layers in a locally inhomogeneous distribution, which can be understood to mean in particular an asymmetric distribution. Here, an asymmetric distribution is understood to mean that there is no axis of symmetry in the ferroelectric layer 2 parallel to the direction of current flow, i.e. from electrode 1 to electrode 2 (vertical in this embodiment example). The dopant concentration is typically 2 percent to 4 percent, i.e., the chemical element aluminum is introduced into the ferroelectric layer 2 at a level between 2 percent to 4 percent (mass percent or volume percent) relative to hafnium oxide in the example shown. The materials used can be easily integrated into existing CMOS processes, so that nothing stands in the way of manufacturing such components on an industrial scale.

FIG. 2 shows a diagram in which the polarization of the ferroelectric layer 2 is plotted against the applied electrical voltage (labeled “voltage”). The polarization-voltage curve achieved by the locally inhomogeneous distribution of the dopant can be seen. Since a steeper switching behavior can be achieved with such a component or a process in which a locally inhomogeneous doping of the ferroelectric layer 2 is performed, such a component is also favorable for memory applications since a smaller variability can be achieved.

FIG. 3 shows a cross-sectional view of another electronic component corresponding to FIG. 1, but in this case the positions of layers 2 and 4 have now been exchanged, i.e. ferroelectric layer 2 is now in direct contact with lower electrode 5. Recurring features are marked with identical reference signs in all figures. FIG. 4 shows the resulting polarization-voltage curve in a representation corresponding to FIG. 2, which is now different according to the changed arrangement of the layers.

In a process for fabricating the illustrated electronic components, the layers are typically deposited starting from the bottom electrode 5, for example by atomic layer deposition, chemical vapor deposition, or physical vapor deposition. The ferroelectric layer 2 or the ferroelectric layers 2, 3, and 4, if several of these layers are introduced (possibly also deposited one on top of the other to ultimately form a single layer in the component), are usually generated by dopants of the same charge or homogeneously distributed dopants of different electrical charge, which is also referred to as codoping, since two or more dopants are present in the entire layer. That is, the first dopant is used to adjust the ferroelectric or antiferroelectric properties (and may be present in a homogeneous distribution), the second dopant with a non-oxide element of the ferroelectric or antiferroelectric material with a different number of free outer electrons is introduced in a spatially inhomogeneous distribution for targeted local influencing of the properties of the respective layer.

The electronic components shown in FIGS. 1 and 3, or components with a correspondingly similar structure, can be used in all areas in which (anti-)ferroelectric layers with a fluoride structure (in particular HfO₂, ZrO₂, HfₓZr₁₋ₓO₂) are used, for example to compensate for unwanted imprints. Often, when integrating ferroelectric material stacks into existing semiconductor manufacturing technologies, different processes or process conditions are used for the deposition of electrodes, which causes an intrinsic asymmetry and thus imprint, which should be compensated. The local doping approach presented here is a cost-effective alternative to adapting a larger manufacturing flow with numerous dependencies.

On the other hand, this can be used specifically for antiferroelectric devices, which should behave in a non-volatile manner. Local doping allows the antiferroelectric switching operating point to be shifted such that no switching back occurs at neutral external potential. This solution represents a CMOS-compatible variant to the approach mentioned at the beginning by means of asymmetric exit work of non-CMOS-compatible electrode materials. Another field of application are components, which should behave differently depending on the direction of the voltage change, both electrically and in mechanical expansion (inverse piezoelectric effect) as well as pyroelectrically.

In the case of antiferroelectric buffer capacitors, local doping can be used both to shift the point of application of antiferroelectric (energy) storage and to improve reliability by moving away from the breakdown voltage. The described electronic component can thus be used as a buffer capacitor or be designed as a buffer capacitor. Local doping and imprint generation can be used selectively to optimize the reliability, especially data retention, of ferroelectric devices. One example here is a targeted compensation of depolarization fields in ferroelectric field-effect transistors.

Directed doping can simplify the peripheral circuitry of arrays of nonvolatile memory elements because operations can be shifted toward a voltage polarity. For example, it is often undesirable to pass high negative voltages.

The project that led to this application was funded by the ECSEL Joint Undertaking (JU) under Grant Agreement No. 826655. JU receives support from the European Union's Horizon 2020 research and innovation program and from Belgium, France, Germany, the Netherlands and Switzerland.

What is claimed is:

1-9. (canceled)

10. An electronic component with at least one layer of a ferroelectric or antiferroelectric material, wherein the layer is provided, for setting an imprint, with a chemical element as a dopant which has a different number of free outer electrons than a non-oxide element of the ferroelectric or antiferroelectric material, and is introduced into the layer in a locally inhomogeneous distribution.

11. The electronic component according to claim 10, wherein the chemical element is introduced at a proportion with respect to the material with which the layer is formed of between 1 percent and 10 percent.

12. The electronic component according to claim 10, wherein said layer is formed of a ferroelectric material having a fluorite structure.

13. The electronic component according to claim 10, wherein the ferroelectric material is hafnium oxide or zirconium oxide.

14. The electronic component according to claim 10, wherein the chemical element is introduced into the layer in an asymmetric distribution.

15. The electronic component according to claim 10, wherein the chemical element is selected from aluminum, lanthanum and yttrium.

16. The electronic component according to claim 10, wherein the layer is formed with an antiferroelectric material in which the chemical element used for doping is contained in the layer material in such a way that when the external electrical potential is neutral, the polarization of the layer does not switch back.

17. A buffer capacitor as an electronic component according to claim 16.

18. A method of manufacturing an electronic component having at least one layer of a ferroelectric or antiferroelectric material, wherein the layer is provided, for setting an imprint, with a chemical element as a dopant which has a different number of free outer electrons than a non-oxide element of the ferroelectric or antiferroelectric material, and is introduced into the layer in a locally inhomogeneous distribution.
